(19) United States
(12) Patent Application Publication
(10) Pub. No.: US 2025/0120260 A1
(43) Pub. Date: Apr. 10, 2025

(54) DISPLAY DEVICE

(71) Applicant: Samsung Display Co., LTD., Yongin-si (KR)

(72) Inventors: Hyesun Sung, Yongin-si (KR); HYOJUNG KIM, Yongin-si (KR); SEUNGBO SHIM, Yongin-si (KR); YOO-YOUNG PARK, Yongin-si (KR); JI-HYEON SON, Yongin-si (KR); JEONG YONG LEE, Yongin-si (KR); DEOK JUN CHOI, Yongin-si (KR)

(21) Appl. No.: 18/674,243

(22) Filed: May 24, 2024

(30) Foreign Application Priority Data
Oct. 4, 2023 (KR) 10-2023-0132107

(51) Int. Cl. H10K 59/122; G09G 3/00; H10K 50/13

(52) U.S. Cl. CPC H10K 59/122; H10K 50/13; G09G 3/006; G09G 2330/12

(57) ABSTRACT

A display device includes a substrate on which a display area and a non-display area adjacent to the display area are defined, a first electrode disposed in the display area on the substrate, a pixel defining layer disposed on the substrate and exposing at least a portion of the first electrode, a partition wall disposed on the pixel defining layer, where the partition wall includes a first portion including a metal material and a second portion surrounding the first portion and including a metal oxide, a light emission layer disposed on the first electrode and the partition wall, where at least a portion of the light emission layer is cut off by the partition wall, and a second electrode disposed on the light emission layer and the partition wall.

This application claims priority to Korean Patent Application No. 10-2023-0132107, filed on Oct. 4, 2023, and all the benefits accruing therefrom under 35 U.S.C. § 119, the content of which in its entirety is herein incorporated by reference.

### BACKGROUND

### 1. Field

The disclosure relates to a display device. More specifically, the disclosure relates to the display device that provides visual information.

### 2. Description of the Related Art

A display device may include a display area that displays an image. The display area may include a pixel area defined as an area that emits light, and the pixel area may be defined as a minimum portion area that emits light.

In the display device, a pixel defining layer may be disposed to separate each pixel area, and a partition wall may be disposed on the pixel defining layer to separate the pixel areas.

### SUMMARY

Embodiments provide a display device capable of detecting defects of a partition wall.

A display device according to an embodiment of the disclosure includes a substrate on which a display area and a non-display area adjacent to the display area are defined, a first electrode disposed in the display area on the substrate, a pixel defining layer disposed on the substrate and exposing at least a portion of the first electrode, a partition wall disposed on the pixel defining layer, where the partition wall includes a first portion including a metal material and a second portion surrounding the first portion and including a metal oxide, a light emission layer disposed on the first electrode and the partition wall, where at least a portion of the light emission layer is cut off by the partition wall and a second electrode disposed on the light emission layer and the partition wall.

In an embodiment, the partition wall may include at least one selected from aluminum (Al), hafnium (Hf), zirconium (Zr), tantalum (Ta), and titanium (Ti).

In an embodiment, the partition wall portion may include a first partition wall which extends in a first direction and a second partition wall portion which extends in a second direction intersecting the first direction.

In an embodiment, the partition wall may include a plurality of partition walls, and each of the plurality of partition walls may have a wave shape in a plan view and spaced apart from each other.

In an embodiment, a width of an upper portion of the partition wall may be greater than a width of a lower portion of the partition wall.

In an embodiment, the light emission layer may include a plurality of organic light emission layers sequentially disposed on the first electrode and the partition wall and a functional layer disposed between the organic light emission layers.

In an embodiment, the light emission layer may be entirely cut off by the partition wall.

In an embodiment, with respect to the substrate, an upper surface of the partition wall may be located at a same level as an upper surface of a portion of the light emission layer disposed directly on the first electrode.

In an embodiment, the organic light emission layers may include a blue organic light emission layer, a green organic light emission layer, and a red organic light emission layer, which are disposed on the first electrode and the partition wall, and the blue organic light emission layer and the green organic light emission layer may be cut off by the partition wall, and the red organic light emission layer continuously may extend in the display area.

In an embodiment, the display area may include a first pixel area, a second pixel area, and a third pixel area, which emit light of different colors from each other, and the organic light emission layers may include a red organic emission layer disposed in the first pixel area, a green organic emission layer disposed in the second pixel area and a blue organic light emission layer disposed in the third pixel area.

In an embodiment, the functional layer may include at least one hole transport layer and at least one electron transport layer, and the electron transport layer closest to the second electrode extends continuously in the display area.

In an embodiment, the second electrode continuously may extend in the display area.

In an embodiment, the display device may further include a signal line disposed in the non-display area and electrically connected to the partition wall to apply a signal to the partition wall and a driver disposed in the non-display area, where the driver may measure a current value of the partition wall based on the signal.

In an embodiment, a display device may further include an insulating layer disposed directly on the partition wall.

In an embodiment, the insulating layer may include an inorganic insulating material.

In an embodiment, the insulating layer may have a single layer structure or a multilayer structure.

In an embodiment, the insulating layer may include at least one selected from silicon oxide (SiO_{X}) and silicon nitride (SiN_{X}).

In an embodiment, the second portion of the partition wall may include at least one selected from aluminum oxide (Al₂O₃), hafnium oxide (HfO₂), zirconium oxide (ZrO₂), tantalum oxide (Ta₂O₅) and titanium oxide (TiO₂).

As the display device according to embodiments of the disclosure includes a partition wall including a first portion including a metal and a second portion including a metal oxide film, such that leakage current may be blocked from flowing into adjacent pixel areas, and short circuit defects of the partition wall may be inspected. In such embodiments, process yield may be improved by inspecting short circuit defects in the partition wall during the manufacturing process of the display device.

### BRIEF DESCRIPTION OF THE DRAWINGS

The above and other features of the invention will become more apparent by describing in further detail embodiments thereof with reference to the accompanying drawings, in which:

FIG. 1 is a plan view showing a display device according to an embodiment of the disclosure;

FIG. 2 is a cross-sectional view of an embodiment of a pixel included in FIG. 1;

FIG. 3 is a cross-sectional view for illustrating the transistor layer included in the pixel of FIG. 2;

FIG. 4 is a cross-sectional view illustrating the thin film encapsulation layer, color conversion layer, and glass encapsulation layer of FIG. 2;

FIG. 5 is a cross-sectional view of an example of a light emission layer included in the pixel of FIG. 1;

FIG. 6 is an example cross-sectional view taken along line I-I′ of FIG. 1 including the light emission layer of FIG. 5;

FIG. 7 is another cross-sectional view taken along line I-I′ of FIG. 1 including the light emission layer of FIG. 5;

FIG. 8 is still another example cross-sectional view taken along line I-I′ of FIG. 1 including the light emission layer of FIG. 5;

FIG. 9 is another example cross-sectional view of the light emission layer included in the pixel of FIG. 1;

FIG. 10 is an example cross-sectional view taken along line I-I′ of FIG. 1 including the light emission layer of FIG. 9;

FIG. 11 is a cross-sectional view taken along line I-I′ of FIG. 1 including the light emission layer of FIG. 9;

FIG. 12 is still another example cross-sectional view taken along line I-I′ of FIG. 1;

FIG. 13 is still another example cross-sectional view taken along line I-I′ of FIG. 1;

FIG. 14 is still another example cross-sectional view taken along line I-I′ of FIG. 1;

FIG. 15 is a plan view showing an example of a partition wall according to an embodiment of the disclosure;

FIG. 16 is a plan view showing another example of the partition wall of FIG. 15; and

FIG. 17 is a plan view for illustrating an embodiment of a method of inspecting a short circuit in a partition wall through the partition wall and signal line.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the invention will be described in detail with reference to the accompanying drawings.

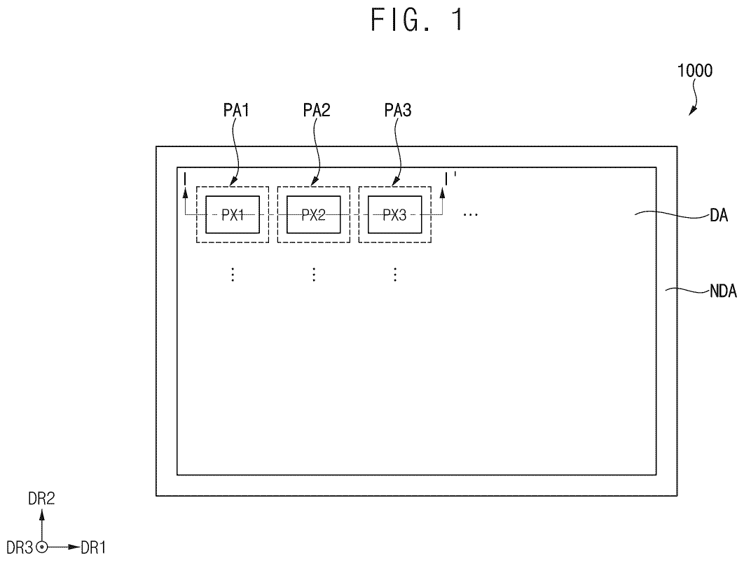

FIG. 1 is a plan view showing a display device according to an embodiment of the disclosure.

Referring to FIG. 1, a display device 1000 according to an embodiment of the disclosure may include plurality of pixels PX1, PX2, and PX3. Each of the pixels may be arranged in a same structure, and may be arranged in a matrix form along the first direction DR1 and the second direction DR2 intersecting the first direction DR1.

In an embodiment, the pixels PX1, PX2, and PX3 may be disposed in a first pixel area PA1, a second pixel area PA2, and a third pixel area PA3, respectively. In such an embodiment, the first pixel PX1 may be disposed in the first pixel area PA1, the second pixel PX2 may be disposed in the second pixel area PA2, and the third pixel PX3 may be disposed in the third pixel area PA3.

In an embodiment, for example, the first pixel PX1 may emit red light, the second pixel PX2 may emit green light, and the third pixel PX3 may emit blue light. In such an embodiment, each of the pixels may emit a color that is a combination of the colors emitted from the first to third pixels PX1, PX2, and PX3, and the display device 1000 may display a video combine with colors emitted from the pixels.

In an embodiment, the display device 1000 may be a micro light emitting diode display device that includes a micro light emitting diode (microLED) as a light emitting element. However, embodiments of the disclosure are not limited thereto. Alternatively, the display device 1000 may include an organic light emitting diode display device including an organic light emitting diode (OLED) as a light emitting device, a quantum dot display device including quantum dots, etc.

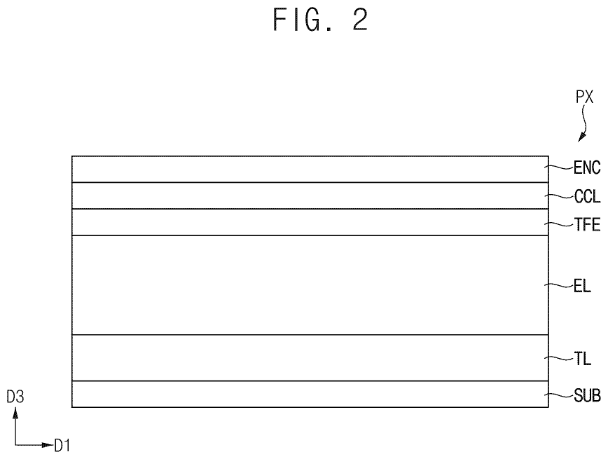

FIG. 2 is a cross-sectional view of an embodiment of a pixel included in FIG. 1.

Referring to FIG. 2, an embodiment of the pixel PX may include a substrate SUB, a transistor layer TL, a light emission layer EL, a thin film encapsulation layer TFE, a color conversion layer CCL, and a glass encapsulation layer ENC. The transistor layer TL, the light emission layer EL, the thin film encapsulation layer TFE, the color conversion layer CCL, and the glass encapsulation layer ENC may be sequentially stacked on the substrate SUB.

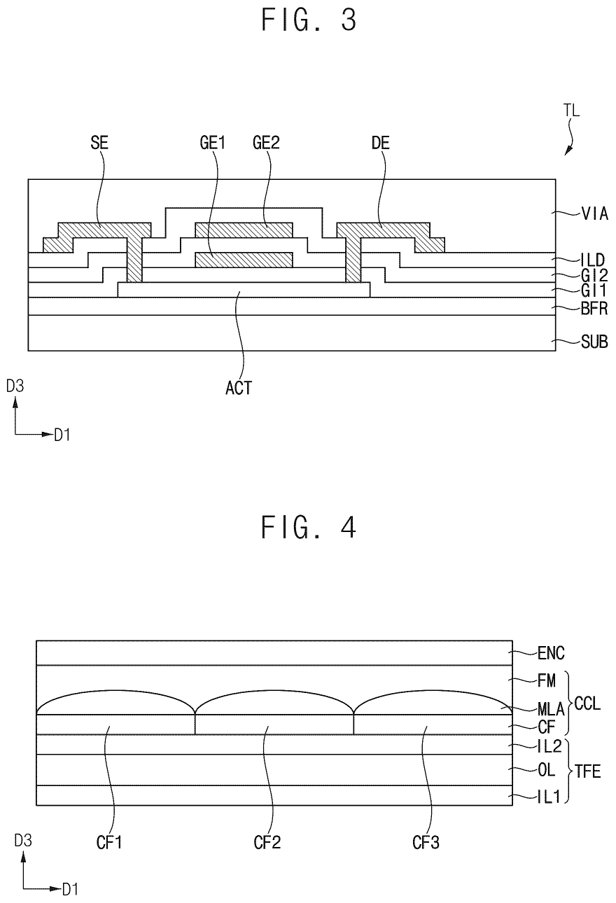

The transistor layer TL may generate a driving current, and the light emission layer EL may emit light corresponding to the driving current. The thin film encapsulation layer TFE may effectively prevent moisture and external air from penetrating into the light emission layer EL. The color conversion layer CCL may convert a color of light emitted from the light emission layer EL, and the glass encapsulation layer ENC may protect the light emission layer EL and the color conversion layer CCL from impact. The substrate SUB, the transistor layer TL, the light emission layer EL, the thin film encapsulation layer TFE, the color shifting layer CCL, and the glass encapsulation layer ENC will be described later in detail with reference to FIGS. 3 to 5.

FIG. 3 is a cross-sectional view for illustrating the transistor layer included in the pixel of FIG. 2.

Referring to FIG. 3, in an embodiment of the pixel, the transistor layer TL may include a substrate SUB, a buffer layer BFR, an active pattern ACT, a first gate insulating layer GI1, a first gate electrode GE1, a second gate insulating layer GI2, a second gate electrode GE2, an interlayer insulating layer ILD, a source electrode SE, a drain electrode DE, and a via insulating layer VIA.

In an embodiment, for example, the substrate SUB may include glass, quartz, plastic, etc. Examples of materials that may be used as the plastic may include polyimide (PI), polyacrylate, polymethylmethacrylate (PMMA), polycarbonate (PC), and polyethylenenaphthalate (PEN), polyvinylidene chloride, polyvinylidene difluoride (PVDF), polystyrene, ethylene vinylalcohol copolymer, polyethersulphone (PES), polyetherimide (PEI), polyphenylene sulfide (PPS), polyallylate, tri-acetyl cellulose (TAC), cellulose acetate propionate, CAP), etc. These may be used alone or in combination with each other.

The buffer layer BFR may be disposed on the substrate SUB. The buffer layer BFR may effectively prevent metal atoms or impurities from penetrating into the active pattern ACT. Additionally, the buffer layer BFR may control the rate of heat provision during the crystallization process to form the active pattern ACT. In an embodiment, for example, the buffer layer BFR may include an inorganic material. Examples of materials that may be used as the inorganic material may include silicon oxide, silicon nitride, and silicon oxynitride. These may be used alone or in combination with each other.

The active pattern ACT may be disposed on the buffer layer BFR. In an embodiment, for example, the active pattern ACT may include a silicon semiconductor material or an oxide semiconductor material. Examples of the silicon semiconductor material that may be used as the active pattern ACT may include amorphous silicon and polycrystalline silicon. Examples of the oxide semiconductor material that may be used as the active pattern ACT may be InGaZnO (IGZO), InSnZnO (ITZO), etc. Examples of the oxide semiconductor material that may be used as the active pattern ACT may be indium (In), gallium (Ga), tin (Sn), zirconium (Zr), vanadium (V), hafnium (Hf), cadmium (Cd), germanium (Ge), and chromium (Cr), titanium (Ti), zinc (Zn), etc. These may be used alone or in combination with each other.

The first gate insulating layer GI1 may be disposed on the buffer layer BFR and may cover the active pattern ACT. In an embodiment, for example, the first gate insulating layer GI1 may include an insulating material. Examples of insulating materials that may be used as the first gate insulating layer GI1 may include silicon oxide, silicon nitride, and silicon oxynitride. These may be used alone or in combination with each other.

The first gate electrode GE1 may be disposed on the first gate insulating layer GI1. In an embodiment, for example, the first gate electrode GEI may include metal, alloy, conductive metal oxide, transparent conductive material, etc. Examples of materials that may be used as the first gate electrode GEI may include silver (Ag), an alloy containing silver, molybdenum (Mo), an alloy containing molybdenum, aluminum (Al), and aluminum containing alloys, aluminum nitride (AIN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), etc. These may be used alone or in combination with each other.

The second gate insulating layer GI2 may be disposed on the first gate insulating layer GI1 and cover the first gate electrode GE1. In an embodiment, for example, the second gate insulating layer GI2 may include an insulating material. Examples of insulating materials that may be used as the second gate insulating layer GI2 may include silicon oxide, silicon nitride, and silicon oxynitride. These may be used alone or in combination with each other.

The second gate electrode GE2 may be disposed on the second gate insulating layer GI2. In an embodiment, for example, the second gate electrode GE2 may include at least one selected from a metal, an alloy, a conductive metal oxide and a transparent conductive material, for example. These may be used alone or in combination with each other.

The interlayer insulating layer ILD may be disposed on the second gate insulating layer GI2 and cover the second gate electrode GE2. In an embodiment, for example, the interlayer insulating layer ILD may include an insulating material.

The source electrode SE and the drain electrode DE may be disposed on the interlayer insulating layer ILD. In an embodiment, for example, the source electrode SE and the drain electrode DE may contact the active pattern ACT. The source electrode SE and the drain electrode DE may include at least one selected from a metal, an alloy, a conductive metal oxide and a transparent conductive material, for example. These may be used alone or in combination with each other.

The via insulating layer VIA may be disposed on the interlayer insulating layer ILD and cover the source electrode SE and the drain electrode DE. In an embodiment, for example, the via insulation layer VIA may include an organic material. Examples of the organic material may include photoresist, polyacrylic resin, polyimide resin, and acrylic resin. These may be used alone or in combination with each other. Accordingly, the via insulation layer VIA may have a substantially flat upper surface.

FIG. 4 is a cross-sectional view illustrating the thin film encapsulation layer, color conversion layer, and glass encapsulation layer of FIG. 2.

Referring to FIG. 4, in an embodiment of the pixel, a first inorganic layer IL1 may be disposed on the via insulating layer (e.g., the via insulating layer VIA in FIG. 3.). In an embodiment, for example, the first inorganic layer IL1 may include an inorganic material. Examples of materials that may be used as the inorganic material may include silicon oxide, silicon nitride, and silicon oxynitride. These may be used alone or in combination with each other.

An organic layer OL may be disposed on the first inorganic layer IL1. In an embodiment, for example, the organic layer OL may include an organic material. Examples of the organic material may include photoresist, polyacrylic resin, polyimide resin, and acrylic resin. These may be used alone or in combination with each other.

A second inorganic layer IL2 may be disposed on the organic layer OL and may include substantially a same material as the first inorganic layer IL1.

A color conversion layer CF may be disposed on the second inorganic layer IL2. The color conversion layer CF may include a first color filter CF1, a second color filter CF2, and a third color filter CF3. The first color filter CF1 may convert a color of light emitted from the light emission layer EL into red, and the second color filter CF2 may convert a color of light emitted from the light emission layer EL into blue. The third color filter CF3 may convert a color of light emitted from the light emission layer EL to green. However, embodiments of the disclosure are not limited thereto.

A micro lens array MLA may be disposed on the color conversion layer CF. The micro lens array MLA may include a plurality of micro lenses. The micro lens array MLA may create a virtual image from images provided from the light emission layer EL and the color conversion layer CF, and may project a virtual image to the user's eyes.

A filler FM may be disposed on the micro lens array MLA. The filler FM may protect the color conversion layer CF and the micro lens array MLA from impact. In an embodiment, for example, the filler FM may include a liquid polymer.

The glass encapsulation layer ENC may be disposed on the filler FM. The glass encapsulation layer ENC may include glass. In an embodiment, for example, the glass encapsulation layer ENC may protect underlying components from impact.

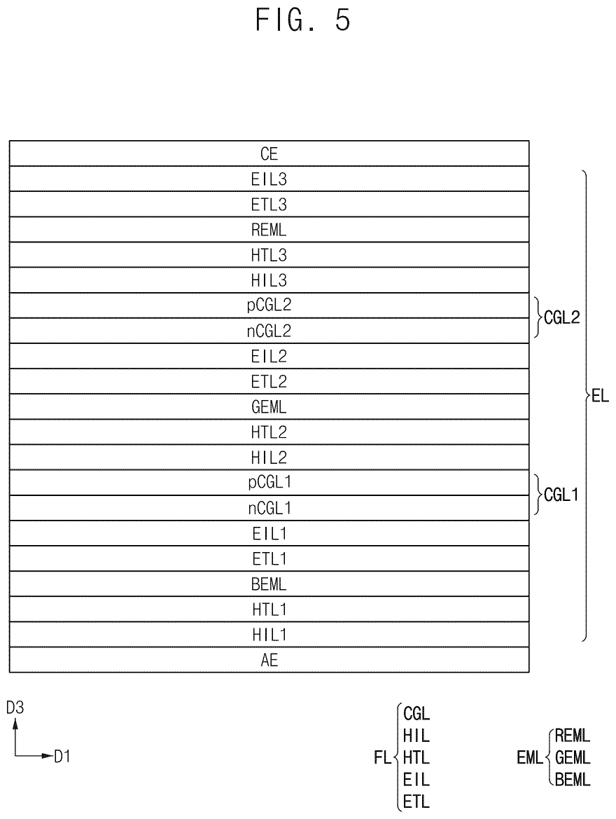

FIG. 5 is a cross-sectional view of an example of a light emission layer included in the pixel of FIG. 1.

Referring to FIG. 5, an embodiment of the light emission layer EL may include an organic light emission layer EML and a functional layer FL. In such an embodiment, a first electrode AE may be disposed under the light emission layer EL, and a second electrode CE may be disposed on the light emission layer EL. That is, the light emission layer EL may be disposed between the first electrode AE and the second electrode CE in a cross-sectional view.

The organic emission layer EML may include a blue organic emission layer BEML, a green organic emission layer GEML, and a red organic emission layer REML. In addition, the functional layer FL may include a first hole injection layer HIL1, a first hole transport layer HTL1, a first electron transport layer ETL1, a first electron injection layer EIL1, a first charge generation layer nCGL1, a second hole injection layer HIL2, a second hole transport layer HTL2, a second electron transport layer ETL2, a second electron injection layer EIL2, a second charge generation layer CGL2, a third hole injection layer HIL3, a third hole transport layer HTL3, a third electron transport layer ETL3, and a third electron injection layer EIL3. In an embodiment, for example, the first charge generation layer nCGL1 may include a first n-type charge generation layer nCGLI and a first p-type charge generation layer pCGL1, and the second charge generation layer CGL2 may include a second n-type charge generation layer nCGL2 and a second p-type charge generation layer pCGL2.

The first hole injection layer HIL1 may be disposed on the first electrode AE. The first hole injection layer HIL1 may inject holes into the first hole transport layer HTL1. The first hole injection layer HTL1 may include at least one selected from copper phthalocyanine (CuPc), N,N-di (naphthalen-1-yl)-N,N′-diphenyl-benzidine (N,N′-Di(naphthalene) and tris-8-hydroxyquinoline aluminum (Alq3), for example. These may be used alone or in combination with each other.

The first hole transport layer HTL1 may be disposed on the first hole injection layer HIL1. The first hole transport layer HTL1 may increase a mobility of holes. In an embodiment, for example, the first hole transport layer HTL1 may include a hole transport material. Examples of materials that may be used as the first hole transport layer HTL1 may include 1,4,5,8,9,11-hexaazatriphenylene-hexanitrile (HATCN), cupper phthalocyanine (CuPc), and poly (3,4)-There may be ethylenedioxythiophene (PEDOT), polyaniline (PANI), N,N-dinaphthyl-N,N′-diphenylbenzidine (NPD), etc. These may be used alone or in combination with each other.

The blue organic emission layer BEML may be disposed on the first hole transport layer HTL1. When electrons and holes are injected into the blue organic light emission layer BEML, the blue organic light emission layer BEML may emit light of a preset color. In an embodiment, for example, the blue organic light emission layer BEML may include an organic material that emits blue light, and may emit blue light.

The first electron transport layer ETL1 may be disposed on the blue organic emission layer BEML. The first electron transport layer ETL1 may increase electron mobility. In an embodiment, for example, the first electron transport layer ETL1 may include an electron transport material. Examples of materials that may be used as the first electron transport layer ETL1 may include 8-Hydroxyquinolinolato-lithium (LiQ), tris(8-hydroxyquinolino) aluminum (Alq3), and 2-(4-biphenylyl)-5-(4-tert-butylpheny)-1,3,4oxadiazole (PBD), 3-(biphenyl-4-yl)-5-(4-tertbutylphenyl)-4-phenyl-4H-1,2,4-triazole (TAZ), Spiro-PBD, etc. These may be used alone or in combination with each other.

The first electron injection layer EIL1 may be disposed on the first electron transport layer ETL1. The first electron injection layer EIL1 may inject electrons into the first electron transport layer ETL1. The first electron injection layer EIL1 may include at least one selected from various organic materials including CuPc, N,N-di(naphthalen-1-yl)-N,N′-diphenyl-benzidine (NPB) and Alq3, etc. These may be used alone or in combination with each other.

The first n-type charge generation layer nCGLI may be disposed on the first electron injection layer EIL1. The first n-type charge generation layer nCGL1 may supply electrons to the blue organic light emission layer BEML. Examples of materials that may be used as the first n-type charge generation layer nCGL1 may include metals, alloys, metal oxides, reflective conductive materials, and organic materials doped with n-type materials. These may be used alone or in combination with each other.

The first p-type charge generation layer pCGL1 may be disposed on the first n-type charge generation layer nCGL1. The first p-type charge generation layer pCGL1 may supply holes to the green organic light emission layer GEML. Examples of materials that may be used as the first p-type charge generation layer pCGL1 may include metals, alloys, metal oxides, reflective conductive materials, and organic materials doped with p-type materials. These may be used alone or in combination with each other.

The second hole injection layer HIL2 may be disposed on the first p-type charge generation layer pCGL1. The second hole injection layer HIL2 may inject holes into the second hole transport layer HTL2. The second hole injection layer HIL2 may include at least one selected from various organic materials including CuPc, NPB and Alq3. These may be used alone or in combination with each other.

The second hole transport layer HTL2 may be disposed on the second hole injection layer HIL2. The second hole transport layer HTL2 may increase a mobility of holes. In an embodiment, for example, the second hole transport layer HTL2 may include a hole transport material.

The green organic emission layer GEML may be disposed on the second hole transport layer HTL2. When electrons and holes are injected into the green organic light emission layer GEML, the green organic light emission layer GEML may emit light of a preset color. In an embodiment, for example, the green organic light emission layer GEML may include an organic material that emits green light, and may emit green light.

The second electron transport layer ETL2 may be disposed on the green organic light emission layer GEML. The second electron transport layer ETL2 may increase electron mobility. In an embodiment, for example, the second electron transport layer ETL2 may include an electron transport material.

The second electron injection layer EIL2 may be disposed on the second electron transport layer ETL2. The second electron injection layer EIL2 may inject electrons into the second electron transport layer ETL2. The second electron injection layer EIL2 may include substantially a same material as the second electron transport layer ETL2.

The second n-type charge generation layer nCGL2 may be disposed on the second electron injection layer EIL2. The second n-type charge generation layer nCGL2 may supply electrons to the green organic light emission layer GEML. Examples of materials that may be used as the second n-type charge generation layer nCGL2 may include metals, alloys, metal oxides, reflective conductive materials, organic materials doped with n-type materials, etc. These may be used alone or in combination with each other.

The second p-type charge generation layer pCGL2 may be disposed on the second n-type charge generation layer nCGL2. The second p-type charge generation layer pCGL2 may supply holes to the red organic emission layer REML. Examples of materials that may be used as the second p-type charge generation layer pCGL2 may include metals, alloys, metal oxides, reflective conductive materials, organic materials doped with p-type materials, etc. These may be used alone or in combination with each other.

The third hole injection layer HIL3 may be disposed on the second p-type charge generation layer pCGL2. The third hole injection layer HIL3 may inject holes into the third hole transport layer HTL3. The third hole injection layer HIL3 may include substantially a same material as the first hole injection layer HIL1.

The third hole transport layer HTL3 may be disposed on the third hole injection layer HIL3. The third hole transport layer HTL3 may increase a mobility of holes. In an embodiment, for example, the third hole transport layer HTL3 may include a hole transport material.

The red organic emission layer REML may be disposed on the third hole transport layer HTL3. When electrons and holes are injected into the red organic light emission layer REML, the red organic light emission layer REML may emit light of a preset color. In an embodiment, for example, the red organic emission layer REML may include an organic material that emits red light, and may emit red light.

The third electron transport layer ETL3 may be disposed on the red organic emission layer REML. The third electron transport layer ETL3 may increase electron mobility. In an embodiment, for example, the third electron transport layer ETL3 may include an electron transport material.

The third electron injection layer EIL3 may be disposed on the third electron transport layer ETL3. The third electron injection layer EIL3 may inject electrons into the third electron transport layer ETL3. The third electron injection layer EIL3 may include substantially a same material as the second electron injection layer EIL2.

The second electrode CE may be disposed on the third electron injection layer EIL3. In an embodiment, for example, the second electrode CE may include at least one selected from a metal, an alloy, a metal oxide and a reflective conductive material. Examples of materials that may be used as the second electrode CE may include silver (Ag), an alloy containing silver, molybdenum (Mo), an alloy containing molybdenum, aluminum (Al), and an alloy containing aluminum. Alloy, aluminum nitride (AIN), tungsten (W), tungsten nitride (WN), copper (Cu), nickel (Ni), chromium (Cr), chromium nitride (CrN), titanium (Ti), tantalum (Ta), Examples of materials that may be used as the second electrode CE may further include platinum (Pt), scandium (Sc), indium tin oxide (ITO), and indium zinc oxide (IZO), etc. These may be used alone or in combination with each other.

In an embodiment, as shown in FIG. 5, the blue organic emission layer BEML, the green organic emission layer GEML, and the red organic emission layer REML may be sequentially disposed on the first electrode AE, but embodiments of the disclosure are not limited thereto. In an embodiment, for example, the order of the blue organic emission layer BEML and the green organic emission layer GEML in FIG. 5 may be changed.

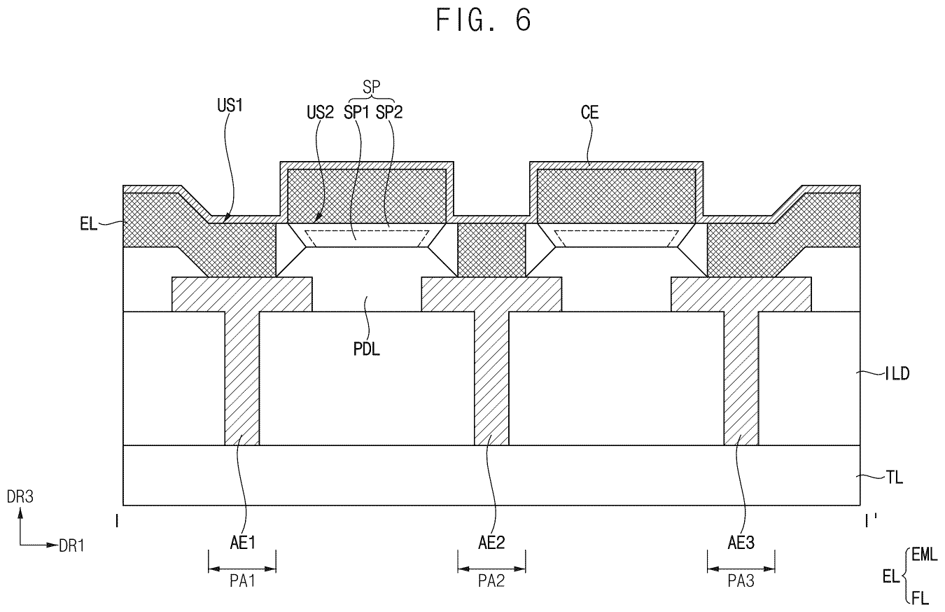

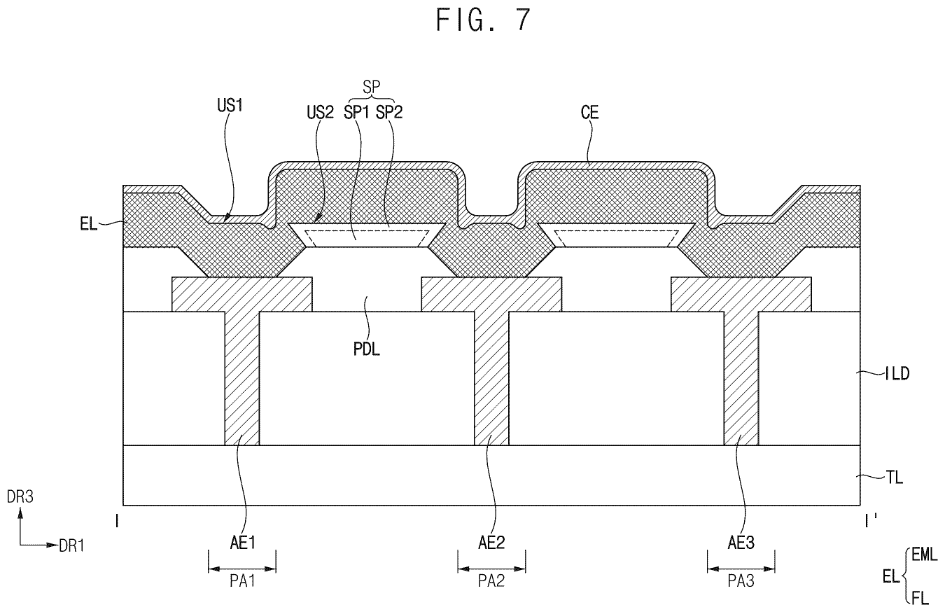

FIG. 6 is an example cross-sectional view taken along line I-I′ of FIG. 1 including the light emission layer of FIG. 5. FIG. 7 is another cross-sectional view taken along line I-I′ of FIG. 1 including the light emission layer of FIG. 5. Specifically, FIG. 7 shows an embodiment in which the light emission layer EL is deposited continuously without cut off in the cross-section. That is, since the light emission layer EL is connected, the light emission layer EL may be continuously deposited on the side of the partition wall SP.

Referring to FIGS. 1 to 7, in an embodiment, the transistor layer TL may be disposed in the display area DA on the substrate SUB. In an embodiment, for example, the transistor layer TL may include various drivers, wiring for driving the light emission layer EL.

An interlayer insulating layer ILD may be disposed on the transistor layer TL. The interlayer insulating layer ILD may effectively prevent contact between first to third first electrodes AE1, AE2, and AE3 and the transistor layer TL. In an embodiment, for example, examples of materials that may be used as the interlayer dielectric layer ILD may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), zinc oxide (ZnO_{X}), etc. These may be used alone or in combination with each other.

A plurality of first electrodes (e.g., the first to third first electrodes AE1, AE2, and AE3) may be disposed on the interlayer insulating layer ILD. In an embodiment, the first first electrode AE1 may be disposed in the first pixel area PA1, the second first electrode AE2 may be disposed in the second pixel area PA2, and the third first electrode AE3 may be disposed in the third pixel area PA3. Examples of materials that may be used as the first to third first electrodes AE1, AE2, and AE3 may include silver (Ag), an alloy containing silver, molybdenum (Mo), and molybdenum containing Alloys containing aluminum (Al), aluminum-containing alloys, aluminum nitride (AIN), tungsten (W), tungsten nitride (WN), copper (Cu), nickel (Ni), chromium (Cr), chromium nitride (CrN)), titanium (Ti), tantalum (Ta), platinum (Pt), scandium (Sc), indium tin oxide (ITO), indium zinc oxide (IZO), etc. These may be used alone or in combination with each other. Each of the first to third first electrodes AE1, AE2, and AE3 may correspond to the first electrode AE of FIG. 2.

A pixel defining layer PDL may be disposed on the interlayer insulating layer ILD. The pixel defining layer PDL may define or be provided with openings to expose at least a portion of an upper surface of each of the first-first, the first-second, and the first-third electrodes AE1, AE2, and AE3. In an embodiment, the pixel defining layer PDL may cover edges of each of the first-first, the first-second, and the first-third electrodes AE1, AE2, and AE3.

The pixel defining layer PDL may include an organic material. Examples of the organic material may include photoresist, polyacrylic resin, polyimide resin, and acrylic resin. These may be used alone or in combination with each other.

The partition wall SP may be disposed on the pixel defining layer PDL. The partition wall SP may be disposed between the first to third pixel areas PA1, PA2, and PA3. In an embodiment, the partition wall SP may extend in the first direction DR1 or the second direction DR2.

In an embodiment, the partition wall SP may include a first portion SP1 including or made of a metal. In an embodiment, for example, the first portion SP1 may include at least one selected from aluminum (Al), hafnium (Hf), zirconium (Zr), tantalum (Ta), and titanium (Ti). These may be used alone or in combination with each other.

In an embodiment, the partition wall SP may include a first portion SP1 including a metal and a second portion SP2 surrounding the first portion SP1 and including a metal oxide. After forming a preliminary partition wall including a metal, the surface of the preliminary partition wall may be oxidized to form the partition wall SP.

In an embodiment, for example, the second portion SP2 of the partition wall SP may include at least one selected from aluminum oxide (Al₂O₃), hafnium oxide (HfO₂), zirconium oxide (ZrO₂), tantalum oxide (Ta₂O₅) and titanium oxide (TiO₂), for example. These may be used alone or in combination with each other.

In an embodiment, the second portion SP2 of the partition wall SP may have a high dielectric constant. In an embodiment, for example, where the second portion SP2 of the partition wall SP includes aluminum oxide (Al₂O₃), the second portion SP2 of the partition wall SP may have a dielectric constant in a range of about 9 to about 12.

In an embodiment, the partition wall SP may have an upper width greater than a lower width in cross section. Specifically, the partition wall SP may have an inverted trapezoidal cross-sectional shape. However, embodiments of the disclosure are not limited thereto, and the partition wall SP may have various shapes in which the upper width is greater than the lower width. This will be described later in greater detail with reference to FIG. 9.

In an embodiment, a width of the lower portion of the partition wall SP may be substantially the same as a width of the upper portion of the pixel defining layer PDL. In another embodiment, a width of the lower portion of the partition wall SP may be different from a width of the upper portion of the pixel defining layer PDL.

The light emission layer EL may be disposed on the partition wall SP and the first to third first electrodes AE1, AE2, and AE3. The light emission layer EL may include the functional layer FL and the organic light emission layer EML. At least a portion of the light emission layer EL may be cut off (or disconnected) by the partition wall SP. In an embodiment, the light emission layer EL may be entirely cut off by the partition wall SP. The functional layer FL may be entirely cut off by the partition wall SP.

In an embodiment, an upper surface US2 of the partition wall SP with respect to the substrate SUB may be located on a same level as an upper surface US1 of a portion of the light emission layer EL disposed directly on the first electrode AE.

In an embodiment, as shown in FIG. 7, the light emission layer EL may be deposited continuously without being cut off by the partition wall SP. In such an embodiment, the light emission layer EL may be deposited on the side of the partition wall SP and have a continuous shape in cross section. However, embodiments of the disclosure are not limited thereto. In another embodiment, the light emission layer EL may have a shape in which a part of the light emission layer EL is cut off by the partition wall SP and another part of the light emission layer EL is deposited continuously.

The second electrode CE may be disposed on the light emission layer EL. In an embodiment, the second electrode CE may continuously extend in the display area DA. That is, the second electrode CE may continuously extend in the display area DA without being cut off by the partition wall SP. Examples of materials that may be used as the second electrode CE may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), and indium zinc oxide (IZO), etc. These may be used alone or in combination with each other.

In an embodiment, for example, a color conversion layer and/or a color filter may be further disposed on the light emission layer EL. The color conversion layer may include quantum dots and may convert the wavelength of light emitted from the organic light emission layer EML. The color filter may selectively transmit light having a specific wavelength. The color conversion layer or the color filter may be disposed in at least one direction in which light emitted from the light emission layer EL travels.

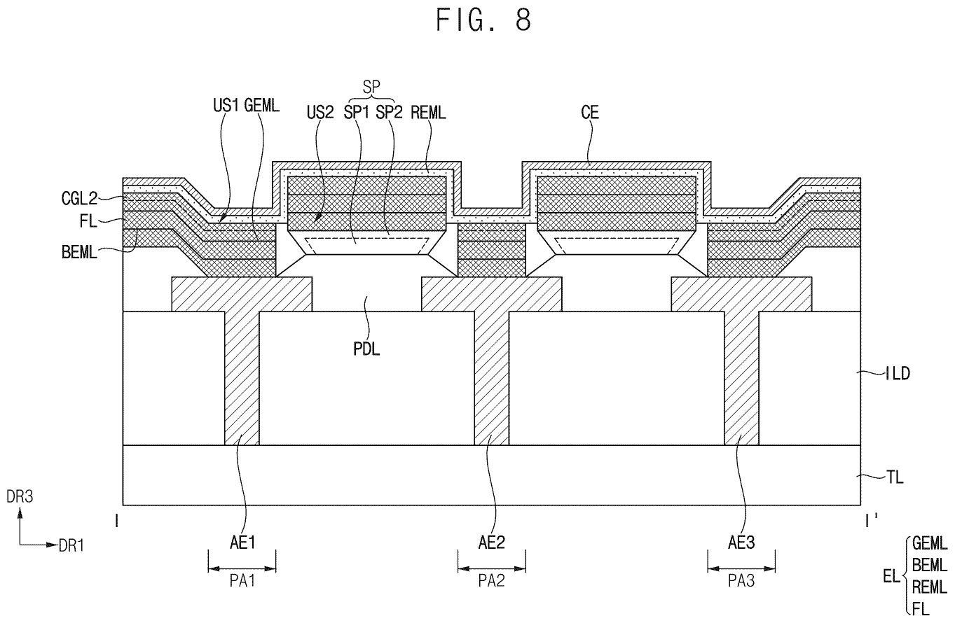

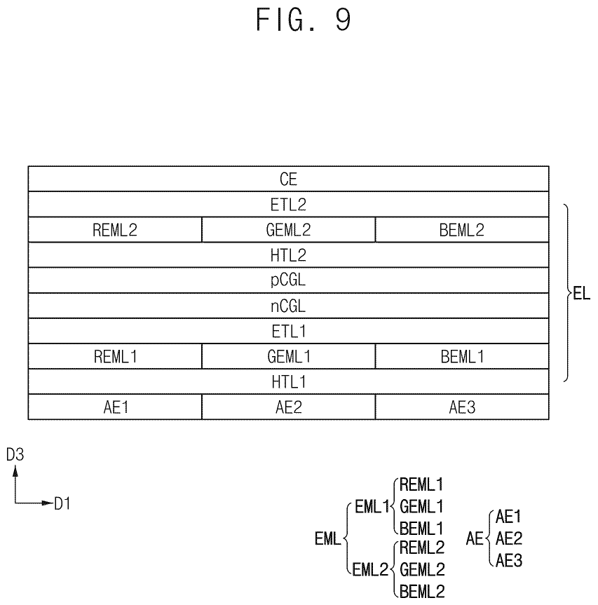

FIG. 8 is still another example cross-sectional view taken along line I-I′ of FIG. 1 including the light emission layer of FIG. 5. The light emission layer shown in FIG. 8 may be substantially the same as or similar to the light emission layer shown in FIG. 6 except for the light emission layer (e.g., the light emission layer EL of FIG. 5). Hereinafter, any repetitive detailed descriptions of the same or like elements as those described above will be omitted or simplified.

Referring to FIG. 8, in an embodiment, a light emission layer EL may be disposed on the side and upper surface US2 of the partition wall SP. Specifically, the light emission layers EL may be disposed on the first to third first electrodes AE1, AE2, and AE3 or on the partition wall SP.

In an embodiment, a level of the upper surface US2 of the partition wall SP with respect to the substrate (e.g., the substrate SUB in FIG. 3) may be the same as a level of (e.g., a lower surface of) the second charge generation layer CGL2 portion of the light emission layer EL disposed on the first to third first electrodes AE1, AE2, and AE3 with respect to the substrate.

In an embodiment, for example, the second electrode CE may be disposed on the light emission layer EL. That is, the second electrode CE and the red organic light emission layer REML extend continuously without being cut off by the partition wall SP in the display area (e.g., the display area DA in FIG. 1). The red organic emission layer REML may include an organic material that emits red light.

FIG. 9 is another embodiment cross-sectional view of the light emission layer included in the pixel of FIG. 1.

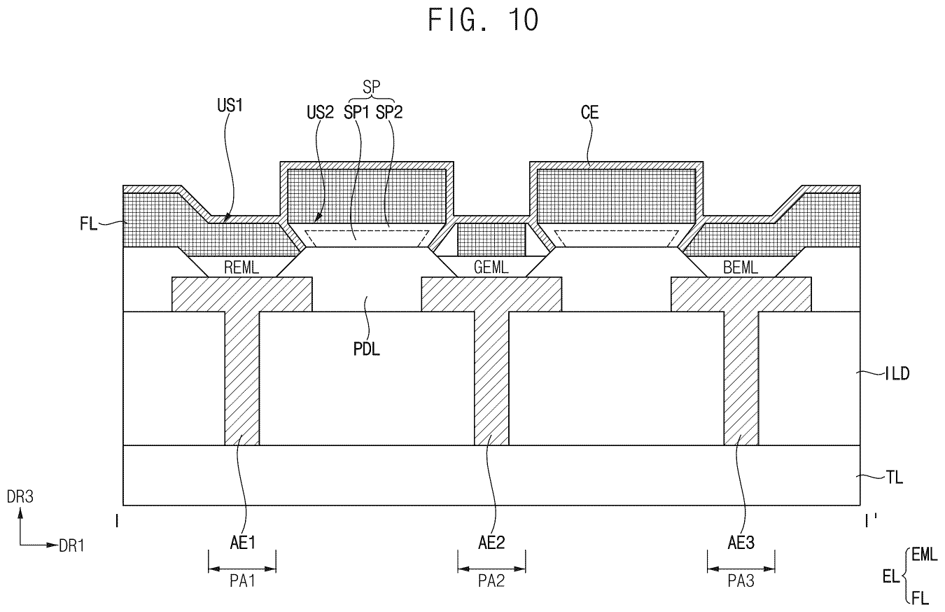

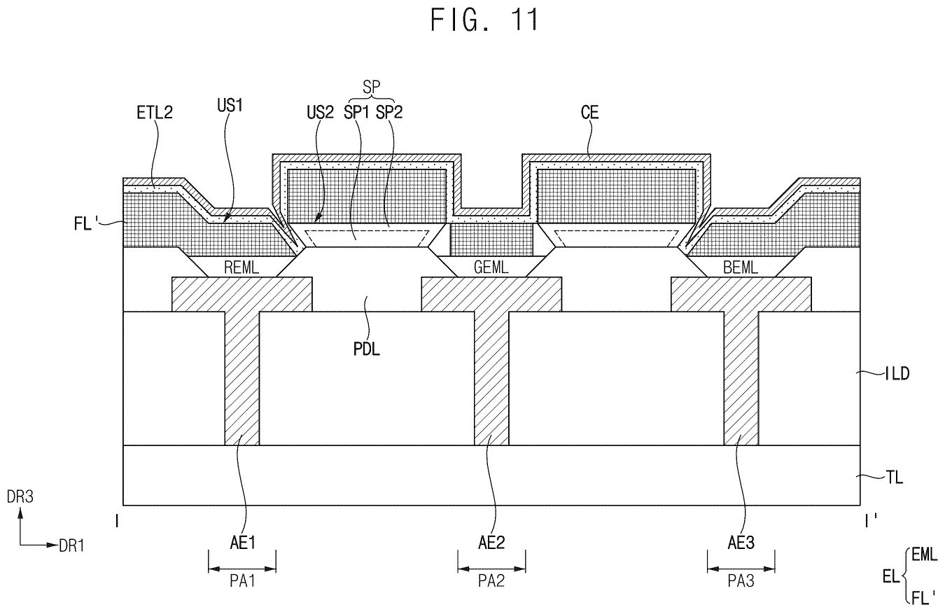

Referring to FIG. 9, an embodiment of the light emission layer EL may include the organic light emission layer EML and the functional layer (e.g., the functional layer FL in FIG. 10). In such an embodiment, the first electrode AE may be disposed below the light emission layer EL, and the second electrode CE may be disposed on the light emission layer EL. That is, in cross-section, the light emission layer EL may be disposed between the first electrode AE and the second electrode CE.

The first electrode AE may include the first first electrode AE1 disposed in the first pixel area (e.g., the first pixel area PA1 in FIG. 10), the second first electrode AE2 disposed in the second pixel area (e.g., the second pixel area PA2 in FIG. 10), and the third first electrode AE3 disposed in the third pixel area (e.g., the third pixel area PA3 in FIG. 10).

The organic emission layer EML may include a first organic emission layer EML1 and a second organic emission layer EML2. The first organic emission layer EML1 may include a first red organic emission layer REML1, a first green organic emission layer GEML1, and a first blue organic emission layer BEML1. The second organic emission layer EML2 may include a second red organic emission layer REML2, a second green organic emission layer GEML2, and a second blue organic emission layer BEML2.

The functional layer (e.g., the functional layer FL in FIG. 10) may include a hole transport layer HTL, a charge generation layer CGL, and an electron transport layer ETL. The charge generation layer CGL may include an n-type charge generation layer nCGL and a p-type charge generation layer pCGL. The hole transport layer HTL may include a first hole transport layer HTL1 and a second hole transport layer HTL2. The electron transport layer ETL may include a first electron transport layer ETL1 and a second electron transport layer ETL2.

The functional layer (e.g., the functional layer FL in FIG. 10) may be disposed entirely on the display area (e.g., the display area DA in FIG. 1).

The first electrode AE may include at least one selected from a metal, an alloy, a metal oxide and a reflective conductive material, for example.

The first hole transport layer HTL1 may be disposed on the first electrode AE. In an embodiment, for example, the first hole transport layer HTL1 may include a hole transport material.

The first red organic emission layer REML1, the first green organic emission layer GEML1, and the first blue organic emission layer BEML1 may be disposed on the first hole transport layer HTL1. The first red organic emission layer REML1, the first green organic emission layer GEML1, and the first blue organic emission layer BEML1 may be disposed in (or directly on) a same layer as each other. That is, the first red organic emission layer REML1 may be disposed in the first pixel area (e.g., the first pixel area PA1 in FIG. 10), the first green organic emission layer GEML1 may be disposed in the second pixel area (e.g., the second pixel area PA2 of FIG. 10), and the first blue organic light emission layer BEML1 may be disposed in the third pixel area (e.g., the third pixel area PA3 of FIG. 10).

In an embodiment, for example, the first red organic emission layer REML1 may include an organic material that emits red light, and may emit red light. The first green organic emission layer GEML1 may include an organic material that emits green light, and may emit green light. The first blue organic emission layer BEML1 may include an organic material that emits blue light, and may emit blue light.

The first electron transport layer ETL1 may be disposed on the first organic light emission layer EML1. In an embodiment, for example, the first electron transport layer ETL1 may include an electron transport material.

The n-type charge generation layer nCGL may be disposed on the first electron transport layer ETL1. Examples of materials that may be used as the n-type charge generation layer nCGL may include metals, alloys, metal oxides, reflective conductive materials, organic materials doped with n-type materials, etc. These may be used alone or in combination with each other.

The p-type charge generation layer pCGL may be disposed on the n-type charge generation layer nCGL. Examples of materials that may be used as the p-type charge generation layer pCGL may include metals, alloys, metal oxides, reflective conductive materials, organic materials doped with p-type materials, etc. These may be used alone or in combination with each other.

The second hole transport layer HTL2 may be disposed on the p-type charge generation layer pCGL. In an embodiment, for example, the second hole transport layer HTL2 may include a hole transport material.

The second red organic emission layer REML2, the second green organic emission layer GEML2, and the second blue organic emission layer BEML2 may be disposed on the second hole transport layer HTL2. The second red organic emission layer REML2, the second green organic emission layer GEML2, and the second blue organic emission layer BEML2 may be disposed in (or directly on) a same layer as each other.

For example, the second red organic emission layer REML2 may include an organic material that emits red light, and may emit red light. The second green organic light emission layer GEML2 may include an organic material that emits green light, and may emit green light. The second blue organic emission layer BEML2 may include organic material that emits blue light, and may emit blue light.

The second electron transport layer ETL2 may be disposed on the second organic light emission layer EML2. In an embodiment, for example, the second electron transport layer ETL2 may include an electron transport material.

That is, the light emission layer EL may have a structure in which two organic light emission layers EML are stacked. However, embodiments of the disclosure are not limited thereto, and alternatively, the light emission layer EL may have a structure in which one or three or more organic light emission layers EML are stacked.

The second electrode CE may be disposed on the second electron transport layer ETL2. In an embodiment, for example, the second electrode CE may include at least one selected from a metal, an alloy, a metal oxide and reflective conductive material. These may be used alone or in combination with each other.

Although an embodiment of the light emission layer EL shown in FIG. 9 includes the first and second electron transport layers ETL1 and ETL2 and the first and second hole transport layers HTL1 and HTL2, the disclosure is not limited thereto. In another embodiment, as shown in FIG. 5, the light emission layer EL may further include functional layers such as an electron injection layer EIL and a hole injection layer HIL in addition to the electron transport layer ETL and the hole transport layer HTL.

FIG. 10 is an example cross-sectional view taken along line I-I′ of FIG. 1 including the light emission layer of FIG. 9.

The light emission layer shown in FIG. 10 may be substantially the same as or similar to the light emission layer shown in FIG. 6 except for the shape of the light emission layer EL. Hereinafter, any repetitive detailed descriptions of the same or like elements as those described above will be omitted or simplified.

Referring to FIGS. 9 and 10, the transistor layer TL may be disposed in the display area (e.g., the display area DA in FIG. 1) on a substrate (e.g., the substrate SUB in FIG. 3).

An interlayer insulating layer ILD may be disposed on the transistor layer TL. The first to third first electrodes AE1, AE2, and AE3 may be disposed on the interlayer insulating layer ILD.

The transistor layer TL may be electrically connected to the first first electrode AE1, the second first electrode AE2, and the third first electrode AE3, which are disposed in the first pixel area PA1, the second pixel area PA2, and the third pixel area PA3, respectively.

The red organic emission layer REML may be disposed in the first pixel area PA1, the green organic emission layer GEML may be disposed in the second pixel area PA2, and the blue organic light emission layer BEML may be disposed in the third pixel area PA3. Specifically, the red organic emission layer REML may be disposed on the first-first electrode AE1, the green organic emission layer GEML may be disposed on the first-second electrode AE2, and the blue organic emission layer BEML may be disposed on the first-third electrode AE3. However, embodiments of the disclosure are not limited thereto.

In an embodiment, the red organic emission layer REML may correspond to the first red organic emission layer REML1 and the second red organic emission layer REML2 of FIG. 9. The green organic light emission layer GEML may correspond to the first green organic light emission layer GEML1 and the second green organic light emission layer GEML2 of FIG. 9. The blue organic light emission layer BEML may correspond to the first blue organic light emission layer BEML1 and the second blue organic light emission layer BEML2 of FIG. 9. That is, the red organic emission layer REML, the green organic emission layer GEML, and the blue organic emission layer BEML may each include two organic emission layers EML. In this case, the functional layer FL such as the electron transport layer ETL, the hole transport layer HTL, and the charge generation layer CGL may be disposed between the organic light emission layers EML.

The partition wall SP may be disposed on the pixel defining layer PDL. The partition wall SP may be disposed between the first to third pixel areas PA1, PA2, and PA3. The partition wall SP of FIG. 10 may be substantially the same as the partition wall SP of FIGS. 6 to 8.

In an embodiment, the upper surface US2 of the partition wall SP may be located at a same level as the upper surface US1 of a portion of the light emission layer EL in the first to third pixel areas PA1, PA2, and PA3 with respect to the substrate (e.g., the substrate SUB in FIG. 3).

The second electrode CE may be disposed on the functional layer FL. The second electrode CE may be continuously connected without being cut off on the display area DA.

The functional layer FL in FIG. 10 corresponds to all of the functional layers in FIG. 9. Specifically, the functional layer FL in FIG. 10 may include the first hole transport layer HTL1, the first electron transport layer ETL1, the n-type charge generation layer nCGL, the p-type charge generation layer pCGL, the second hole transport layer HTL2, and the second electron transport layer ETL2. However, the disclosure is not limited thereto.

In an embodiment, the functional layer FL may be completely cut off by the partition wall SP.

FIG. 11 is a cross-sectional view taken along line I-I′ of FIG. 1 including the light emission layer of FIG. 9.

The light emission layer shown in FIG. 11 may be substantially the same as or similar to the light emission layer shown in FIG. 10 except for the light emission layer (e.g., the light emission layer EL of FIG. 9). Hereinafter, any repetitive detailed descriptions of the same or like elements as those described above will be omitted or simplified.

Referring to FIG. 11, the functional layer FL′ may include a same component as the functional layer FL of FIG. 10 except for the second electron transport layer ETL2.

In an embodiment, the level of the upper surface US2 of the partition wall SP with respect to the substrate (e.g., the substrate SUB in FIG. 3) may be substantially the same as the level of the upper surface US1 of a portion of the light emission layer (e.g., the light emission layer EL in FIG. 9) disposed directly on the first to third first electrodes AE1, AE2, AE3 excluding the second electron transport layer ETL2.

In such an embodiment, the second electron transport layer ETL2 closest to the second electrode CE may continuously extend in the display area (e.g., the display area DA in FIG. 1).

The functional layer FL′ may be cut off by the partition wall SP. In an embodiment, the entire functional layer FL′ may be cut off by the partition wall SP. However, embodiments of the disclosure are not limited thereto. As shown in FIG. 7 and in FIG. 11, the light emission layer EL may be deposited continuously without being cut off on the cross-section.

In an embodiment, the second electron transport layer ETL2 and the second electrode CE of the light emission layer (e.g., the light emission layer EL of FIG. 9) may be continuously extended without being cut off on the display area (e.g., the display area of FIG. 1).

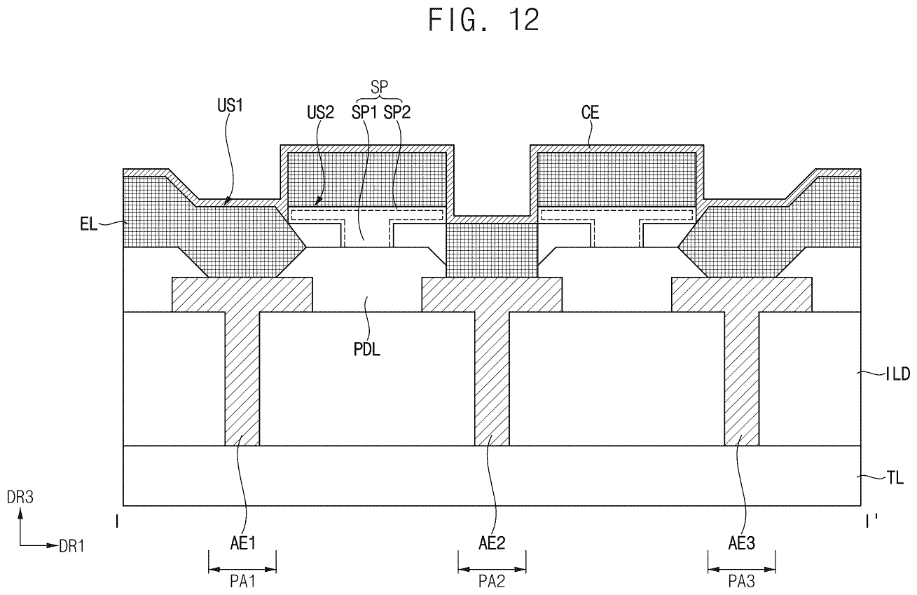

FIG. 12 is still another example cross-sectional view taken along line I-I′ of FIG. 1. The light emission layer shown in FIG. 12 may be substantially the same as or similar to the light emission layer shown in FIG. 4 except for the shape of the partition wall SP. Hereinafter, any repetitive detailed descriptions of the same or like elements as those described above will be omitted or simplified.

Referring to FIG. 12, in an embodiment, the partition wall SP may have a T-shape in cross section. In such an embodiment, a width of the lower portion of the partition wall SP may be substantially the same as or similar to a width of the upper portion of the pixel defining layer PDL.

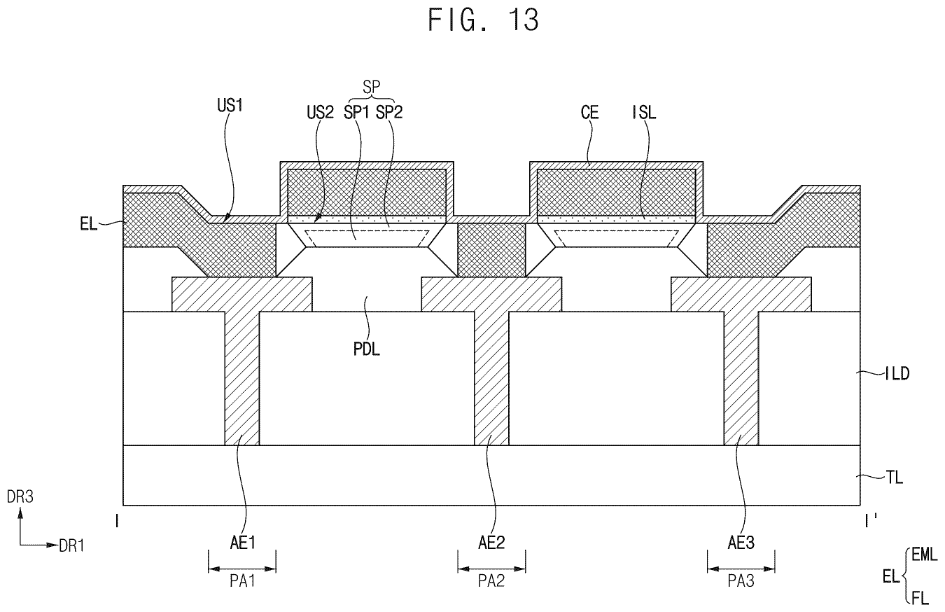

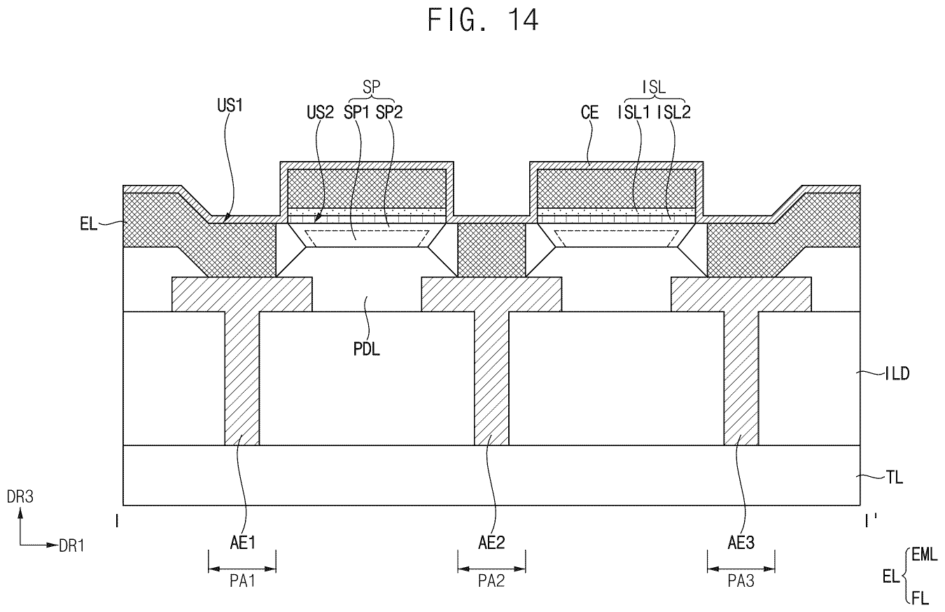

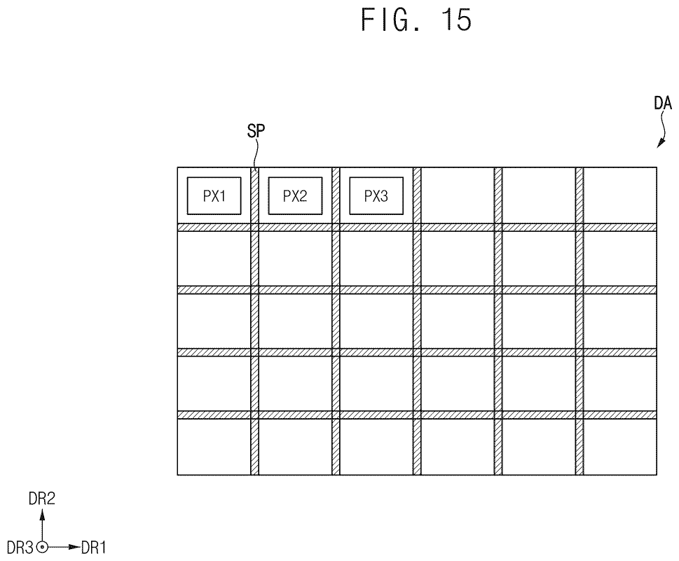

FIG. 13 is still another example cross-sectional view taken along line I-I′ of FIG. 1. FIG. 14 is still another example cross-sectional view taken along line I-I′ of FIG. 1.

The light emission layer shown in FIGS. 13 and 14 may be substantially the same as or similar to the light emission layer shown in FIG. 6, except that an insulating layer ISL is further included. Hereinafter, any repetitive detailed descriptions of the same or like elements as those described above will be omitted or simplified.

Referring to FIGS. 13 and 14, in an embodiment, an insulating layer ISL may be disposed on the partition wall SP.

In an embodiment, the light emission layer EL may be entirely cut off by the partition wall SP and the insulating layer ISL.

In an embodiment, for example, as shown in FIG. 13, the insulating layer ISL may be a single layer. In an embodiment, the insulating layer ISL may include an inorganic material.

In an embodiment, for example, the insulating layer ISL may include SiO_{X}, SiN_{X}, etc. These may be used alone or in combination with each other. Alternatively, the insulating layer ISL may include a metal material, and examples of materials that the insulating layer ISL include may include aluminum (Al), hafnium (Hf), zirconium (Zr), tantalum (Ta), titanium (Ti), etc. These may be used alone or in combination with each other.

Alternatively, as shown in FIG. 14, the insulating layer ISL may be a multilayer including a first insulating layer ISL1 and a second insulating layer ISL2 disposed on the first insulating layer ISL1.

In an embodiment, for example, the first insulating layer ISL1 may include SiO_{X}, SiNx, etc. The second insulating layer ISL2 may include SiO_{X}, SiNx, etc. In such an embodiment, where the insulating layer ISL is a multilayer, the insulating layer ISL may include a structure in which SiO_{X} and SiNx are repeatedly or alternately stacked. Alternatively, the first and second insulating layers ISL1 and ISL2 may include a metal material. However, embodiments of the disclosure are not limited thereto, and the insulating layer ISL may be a multilayer including three or more layers.

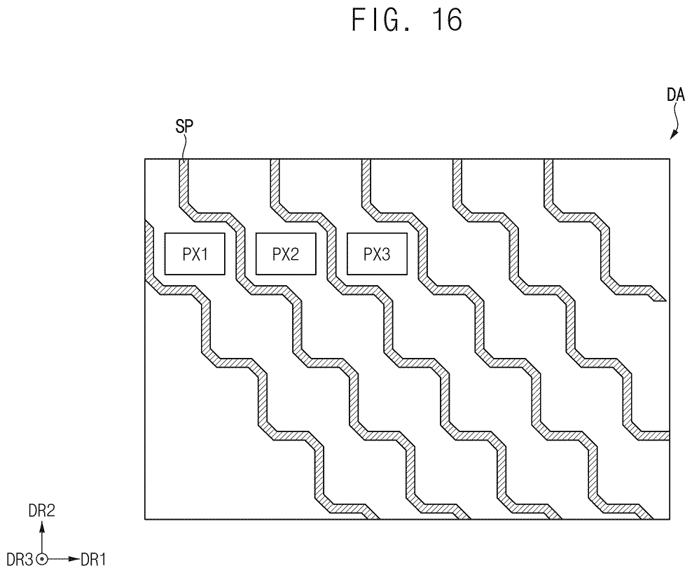

FIG. 15 is a plan view showing an example of a partition wall according to an embodiment of the disclosure. FIG. 16 is a plan view showing another example of the partition wall of FIG. 15.

Referring to FIG. 15, in an embodiment, the partition wall SP may include a first partition wall portion extending in the first direction DR1 and a second partition wall portion extending in the second direction DR2 intersecting the first direction DR1 on the display area DA.

The first partition wall portion extending in the first direction DR1 and the second partition wall portion extending in the second direction DR2 may be disposed on a same layer in the display area DA.

Referring to FIG. 16, the partition wall SP may have a wave shape on the display area DA and may include a plurality of partition walls spaced apart from each other. Although the wave shape may include a repeating ‘L’ shape in an embodiment, the disclosure is not limited thereto.

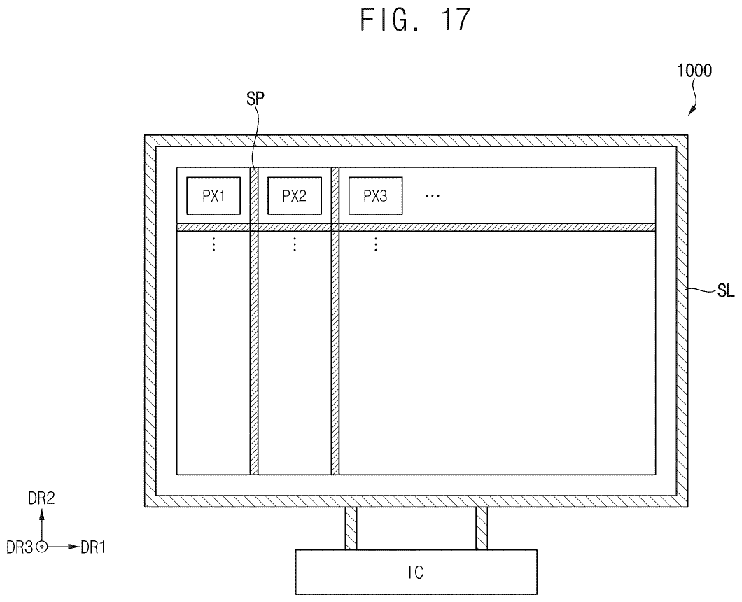

FIG. 17 is a plan view for illustrating an embodiment of a method of inspecting a short circuit in a partition wall through the partition wall and signal line.

Referring to FIGS. 1 and 17, the signal line SL may be placed in the non-display area NDA.

A driver integrated circuit (IC) may be disposed in the non-display area NDA. The driver IC for applying a signal to the partition wall SP may be connected to the signal line SL. The signal line SL may be electrically connected to the partition wall SP on the display area DA.

The signal line SL electrically connected to the partition wall SP may apply a signal to one side of the partition wall SP, and the partition wall SP that has received the signal may transmit a signal to an opposite side thereof connected to a opposite signal line SL. At this time, the received signal by the opposite signal line SL may be transmitted to the driver IC to inspect the partition wall SP for a short circuit.

In an embodiment, the driver IC may compare current values at a first point of the partition wall SP and a second point of the partition wall SP to check whether the partition wall SP has a short circuit. The first point may be any point where the partition wall SP and the signal line SL are connected, and the second point may be an arbitrary point that exists spaced apart with DA between the first point and the display area DA.

In an embodiment, if a current value at the first point of the partition wall SP has a random value and a current value at the second point of the partition wall SP is similar to the random value measured at the first point, it may be determined that a short circuit failure has not occurred in the partition wall SP. In contrast, when a current value at the first point of the partition wall SP has an arbitrary value and a current value at the second point of the partition wall SP converges to 0, it may be determined that a short circuit defect occurs in the partition wall SP.

In a case where the partition wall SP includes an inorganic material such as silicon oxide, silicon nitride, etc., short circuit defects in the partition wall SP may not be inspected through the partition wall SP.

Referring again to FIGS. 1 to 17, as the display device according to embodiments of the disclosure includes a partition wall SP including a first portion SP1 including metal and a second portion SP2 including a metal oxide film, it is possible to block leakage current from flowing into adjacent pixel areas PA1, PA2, and PA3 and inspect the partition wall SP for short circuit defects. In such embodiments, process yield may be improved by inspecting short circuit defects in the partition wall SP during the manufacturing process of the display device.

Embodiments of the disclosure may be applied to a display device and an electronic device including a display device, for example, high-resolution smartphones, mobile phones, smart pads, smart watches, tablet computers, vehicle navigation systems, televisions, computer monitors, laptops, etc.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a substrate on which a display area and a non-display area adjacent to the display area are defined;
a first electrode disposed in the display area on the substrate;
a pixel defining layer disposed on the substrate and exposing at least a portion of the first electrode;
a partition wall disposed on the pixel defining layer, wherein the partition wall includes: a first portion including a metal material; and a second portion surrounding the first portion and including a metal oxide;
a light emission layer disposed on the first electrode and the partition wall, wherein at least a portion of the light emission layer is cut off by the partition wall; and
a second electrode disposed on the light emission layer and the partition wall.

2. The display device of claim 1, wherein the partition wall includes at least one selected from aluminum (Al), hafnium (Hf), zirconium (Zr), tantalum (Ta), and titanium (Ti).

3. The display device of claim 1, wherein the partition wall includes:
a first partition wall portion which extends in a first direction; and
a second partition wall portion which extends in a second direction intersecting the first direction.

4. The display device of claim 1, wherein the partition wall includes a plurality of partition walls, and each of the plurality of partition walls has a wave shape in a plan view and spaced apart from each other.

5. The display device of claim 1, wherein a width of an upper portion of the partition wall is greater than a width of a lower portion of the partition wall.

6. The display device of claim 1, wherein the light emission layer includes:
a plurality of organic light emission layers sequentially disposed on the first electrode and the partition wall; and
a functional layer disposed between the organic light emission layers.

7. The display device of claim 6, wherein the light emission layer is entirely cut off by the partition wall.

8. The display device of claim 6, wherein, with respect to the substrate, an upper surface of the partition wall is located at a same level as an upper surface of a portion of the light emission layer disposed directly on the first electrode.

9. The display device of claim 6, wherein the organic light emission layers include:
a blue organic light emission layer, a green organic light emission layer, and a red organic light emission layer, which are disposed on the first electrode and the partition wall, and
wherein the blue organic light emission layer and the green organic light emission layer are cut off by the partition wall, and the red organic light emission layer continuously extends in the display area.

10. The display device of claim 6, wherein the display area includes a first pixel area, a second pixel area, and a third pixel area, which emit light of different colors from each other, and
wherein the organic light emission layers include:
a red organic emission layer disposed in the first pixel area;
a green organic emission layer disposed in the second pixel area; and
a blue organic light emission layer disposed in the third pixel area.

11. The display device of claim 10, wherein the functional layer include:
at least one hole transport layer; and
at least one electron transport layer, and
wherein the electron transport layer closest to the second electrode extends continuously in the display area.

12. The display device of claim 1, wherein the second electrode continuously extends in the display area.

13. The display device of claim 1, further comprising:
a signal line disposed in the non-display area and electrically connected to the partition wall to apply a signal to the partition wall; and
a driver disposed in the non-display area, wherein the driver measures a current value of the partition wall based on the signal.

14. The display device of claim 1, further comprising:
an insulating layer disposed directly on the partition wall.

15. The display device of claim 14, wherein the insulating layer includes an inorganic insulating material.

16. The display device of claim 14, wherein the insulating layer has a single layer structure or a multilayer structure.

17. The display device of claim 14, wherein the insulating layer includes at least one selected from silicon oxide (SiOx) and silicon nitride (SiNx).

18. The display device of claim 1, wherein the second portion of the partition wall include at least one selected from aluminum oxide (Al₂O₃), hafnium oxide (HfO₂), zirconium oxide (ZrO₂), tantalum oxide (Ta₂O₅) and titanium oxide (TiO₂).
